(19) United States
(12) Patent Application Publication
(10) Pub. No.: US 2010/0151260 A1
(43) Pub. Date: Jun. 17, 2010

(54) METHOD OF COATING A HARD-METAL OR CERMET SUBSTRATE AND COATED HARD-METAL OR CERMET BODY

(76) Inventors: Hartmut Westphal, Dermbach/Rhon (DE); Hendrikus Van Den Berg, Venlo-Blerick (NL)

Correspondence Address: KENNAMETAL INC.;Intellectual Property Department, P.O. BOX 231, 1600 TECHNOLOGY WAY, LATROBE, PA, 15650, US

(21) Appl. No.: 12/161,032

(22) PCT Filed: Nov. 7, 2006
(86) PCT No.: PCT/DE2006/001943

§ 371 Date: Jul. 16, 2008

(30) Foreign Application Priority Data
Jan. 17, 2006 (DE) 10 2006 002 371.4

(51) Int. Cl. B32B 15/04; C23C 14/46

(52) U.S. Cl. 428/457; 204/192.11; 428/689

(57) ABSTRACT

The invention relates to a method of coating a cemented carbide or cermet substrate body by means of PVD, in which the fully sintered substrate body is subjected without further intermediate treatment before PVD coating to a blasting treatment using a particulate blasting agent until the zone close to the surface of the substrate body has a residual stress which is at least essentially of the same magnitude as the residual stress present in the single or first applied PVD layer. The invention further relates to such a coated cemented carbide or cermet body, in particular in the form of a cutting tool.

The invention relates to a method of coating a hard-metal or cermet substrate by means of physical vapor deposition (PVD).

This invention also relates to a coated hard-metal or cermet body.

Hard-metal or cermet bodies having a wide variety of compositions have been proposed for many applications. The substrate composition is adjusted depending on the purpose of the application, special emphasis for example being placed on extreme hardness, resistance to temperature fluctuations or wear resistance, the latter particularly for tools used in chip-producing machining. In certain cases, also coated substrates whose coating was made of one or more layers have been successfully applied. Coating materials include carbides, nitrides, carbonitrides, oxicarbonitrides, oxinitrides or oxides of the metals of the IVa to VIa groups of the periodic table or aluminum compounds, such as Al₂O₃ and TiAlN. For coating substrates, in particular physical or chemical vapor deposition methods are used. In general, physical vapor deposition (PVD) methods have the advantage that the coating can be applied at low temperatures. According to the prior art, the substrates are ground prior to the PVD process. Substrates left with rough substrate surfaces (which is to say in the sintered state) practically have no residual compressive or tensile stress. As a result of the grinding operation, residual compressive stress is produced in the surface of the substrate, ranging between −200 and −1200 MPa for hard-metal. Due to the high-energy procedure employed for introducing the layer-forming components (ions) into the layers, PVD layers always have residual compressive stress ranging between about −1800 and −4000 MPa. The difference in the residual compressive stresses between the coating and substrate for ground substrates is therefore smaller than for substrates left in the sintered state. The difference in the residual stresses between the substrate and coating causes shearing stresses, which negatively impact the adhesion of the coating. For this reason, non-ground substrates coated by means of PVD have poorer cutting performance.

It is the object of the present invention to improve the service life of PVD-coated substrates.

In order to attain this object, a method according to claim 1 and/or the substrate according to claim 9 are proposed.

Further developments of the inventions are described in the dependent claims 2 to 8 and 10.

The core idea of the present invention is that the fully sintered substrate made of a hard-metal or a cermet, without further intermediate treatment before the PVD process, is subjected to a blasting treatment using a particulate blasting agent until the residual stress in the zone of the substrate close to the surface is at least substantially equal to the residual stress present in the single or first PVD layer applied.

Surprisingly, it was found that an adjustment of the residual stress of the substrate in the regions close to the substrate surface to the known residual compressive stress of a PVD layer brings about a considerable improvement in the service life. Using a blasting method, which is known in principle, the regions close to the surface are compacted, resulting in an increase in the residual compressive stress. By adjusting this residual compressive stress to the known residual compressive stress of the first or single PVD layer applied, the cutting performance was improved.

Preferably, a blasting agent comprising particles is used, the particles having a maximum diameter of 600 μm, preferably of no more than 150 μm, and in particular between 15 and 100 μm. The substrate, which according to a further development of the invention is treated using a dry blasting method, is preferably subjected to at least substantially spherical blasting agents or such blasting agents that have a rounded particulate shape. Possible blasting agents are in particular atomized jets, cast iron granules, heavy metal powders or alloys produced thereof, glass, corundum, hard-metal granules and/or fracture-resistant ceramics.

Furthermore, the blasting agent or agents are preferably directed at the substrate by means of compressed air with a pressure of at least 1.0×10⁵ to 10×10⁵ Pa, preferably 1.5×10⁵ to 3.5×10⁵ Pa.

It is particularly advantageous to blast the substrate with blasting-agent particles that are projected perpendicularly at the surface thereof.

The blasting treatment of the above-described type has been successfully applied in particular in conjunction with a subsequent PVD coating, comprising carbides, nitrides, carbonitrides, oxides or oxicarbonitrides of the elements of the IVa to VIa groups of the periodic table or Al₂O₃, AlTiN or AlN. The thickness of the individual layers preferably ranged between 0.1 μm and 10 μm with an overall thickness (in the case of multilayer coatings) of no more than 20 μm.

Accordingly, the object is attained by the coated hard-metal or cermet body according to claim 9, for which the advantages as described above apply.

A hard-metal or cermet body coated in this way is in particular made into a cutting tool for drilling, milling or turning operations.

In a concrete embodiment, indexable inserts were coated with an AlTiN coating, which was applied by means of PVD at 350° to 600° (coating temperature). While the tools, which were coated after sintering without further treatment or after only a grinding treatment, had to be replaced after only a short time due to wear, the service life of corresponding tools having the same configuration, which were processed by the inventive method, namely a blasting treatment lasting between 10 and 60 seconds, after sintering, was considerably improved. This is due to the fact that the PVD layers exhibited residual compressive stress in the range of −1.5 to 3.5 GPa as measured according to the SIN²-_ method, compared to residual tensile stress or very small residual compressive stress in the boundary regions of the substrate close to the surface of no more than 100 MPa, in absolute terms. If, however, as a result of the blasting treatment, particularly using a dry blasting method with round granules of 50 μm and 100 μm, the residual compressive stress of the region of the substrate close to the surface is raised to the residual compressive stress depending on the coating material and the PVD parameters (up to +/−10%), this increase in the residual compressive stress results in considerably improved wear resistance of the tools.

1-10. (canceled)

11. A method of coating a hard-metal or cermet substrate, the method comprising the steps of:
blasting with particles a fully sintered uncoated substrate until a level of residual stress is imparted to a surface region of the substrate that is substantially equal to a level of stress of a PVD coating; and thereafter
PVD coating the surface region of the substrate.

12. The method defined in claim 11 wherein the particles have a maximum diameter of 600 μm.

13. The method defined in claim 11 wherein the particles have a maximum diameter of 150 μm.

14. The method defined in claim 11 wherein the particles have a diameter between 15 μm and 100 μm.

15. The method defined in claim 11 wherein the particles are dry.

16. The method defined in claim 11 wherein the particles are round.

17. The method defined in claim 14 wherein the particles are entrained by a gas and are of cast iron particles, a heavy metal, a heavy-metal alloy, glass, corundum, or a fracture-resistant ceramic.

18. The method defined in claim 14 wherein the particles are directed at the substrate by means of compressed air with a pressure of at least 1.0×10⁵ B 10×10⁵ Pa.

19. The method defined in claim 18 wherein the compressed air has a pressure of about 1.5×10⁵ B 3.5×10⁵ Pa.

20. The method defined in claim 18 wherein the particles are projected perpendicularly at the substrate surface region.

21. The method defined in claim 11, further comprising the step after particle blasting and before PVD coating of:
coating the surface region of the substrate with a layer of carbide, nitride, carbonitride, oxide or oxicarbonitride of the elements of the IVa to VIa groups of the periodic table or Al₂O₃, AlTiN or AlN to a layer thickness of between 0.1 μm and 10 μm.

22. The method defined in claim 11 wherein after particle blasting the substrate is PVD coated on the surface region with a plurality of layers of carbide, nitride, carbonitride, oxide or oxicarbonitride of the elements of the IVa to VIa groups of the periodic table or Al₂O₃, AlTiN or AlN with each layer having a thickness between 0.1 μm and 10 μm and all the layers having a total thickness of at most 20 μm.

23. A hard-metal or cermet body produced by the method of claim 11.

24. A hard-metal or cermet body comprising:
a substrate having a surface region with a residual stress equal substantially to a residual stress of a PVD-applied layer; and
a PVD applied layer on the surface region.

25. The body defined in claim 24 wherein the body is shaped as a cutting tool.
